(19) United States
(12) Patent Application Publication
(10) Pub. No.: US 2018/0248097 A1
(43) Pub. Date: Aug. 30, 2018

(54) THERMOELECTRIC CONVERSION ELEMENT

(71) Applicant: Murata Manufacturing Co., Ltd., Nagaokakyo-shi (JP)

(72) Inventors: Sachiko Hayashi, Nagaokakyo-shi (JP); Shuichi Funahashi, Nagaokakyo-shi (JP)

(21) Appl. No.: 15/962,491

(22) Filed: Apr. 25, 2018

Related U.S. Application Data
(63) Continuation of application No. PCT/JP2016/081585, filed on Oct. 25, 2016.

(30) Foreign Application Priority Data
Nov. 12, 2015 (JP) 2015-222097

(51) Int. Cl. H01L 35/22; H01L 35/20; H01L 35/32; H01L 35/34

(52) U.S. Cl. CPC H01L 35/22; H01L 35/34; H01L 35/32; H01L 35/20

(57) ABSTRACT

A thermoelectric conversion element that includes a laminate having a p-type semiconductor layer, an n-type semiconductor layer, and an insulating layer. The n-type semiconductor layer forms a pn-junction with a region of the p-type semiconductor layer. The insulating layer is provided in a region where the pn-junction is not formed between the p-type semiconductor layer and the n-type semiconductor layer. The laminate also contains 0.005% by weight to 0.009% by weight of carbon.

### CROSS REFERENCE TO RELATED APPLICATIONS

The present application is a continuation of International application No. PCT/JP2016/081585, filed Oct. 25, 2016, which claims priority to Japanese Patent Application No. 2015-222097, filed Nov. 12, 2015, the entire contents of each of which are incorporated herein by reference.

### FIELD OF THE INVENTION

The present invention relates to a thermoelectric conversion element.

### BACKGROUND OF THE INVENTION

Conventionally, thermoelectric conversion elements are known as elements for converting thermal energy into electric energy.

For example, Patent Document 1 discloses a laminated thermoelectric conversion element prepared by degreasing and firing a laminate formed by laminating a p-type semiconductor sheet (p-type layer), an n-type semiconductor sheet (n-type layer) and an insulating layer. The laminated thermoelectric conversion element has a structure in which the p-type layer and the n-type layer are directly bonded to each other in a partial region of the bonding surface and are bonded with an insulating material interposed between the p-type layer and the n-type layer in another region of the bonding surface.

The laminated thermoelectric conversion element can increase the occupancy of a thermoelectric conversion material in the element and can also increase the strength of the element as compared with a π (pie) type thermoelectric conversion element or the like provided with a gap layer for insulating between the p-type layer and the n-type layer. In addition, since the p-type layer and the n-type layer are directly bonded, the circuit resistance in the element can be reduced as compared with the π-type thermoelectric conversion element or the like in which the p-type layer and the n-type layer are bonded with an electrode or the like interposed therebetween. Because of these features, a laminated thermoelectric conversion element has an advantage that the thermoelectric conversion efficiency and the strength can be improved (see, for example, Patent Document 2).
Patent Document 1: Japanese Patent Application Laid-Open No. 2004-281928
Patent Document 2: International Publication WO 2012/011334

### SUMMARY OF THE INVENTION

In addition to a demand to increase a power generation amount of the thermoelectric conversion element, there is a demand to reduce variation in power generation amounts between the thermoelectric conversion elements.

A main object of the present invention is to increase a power generation amount of a thermoelectric conversion element and reduce variation in power generation amounts between thermoelectric conversion elements.

A thermoelectric conversion element according to the present invention includes a laminate. The laminate has a p-type semiconductor layer, an n-type semiconductor layer, and an insulating layer. The n-type semiconductor layer forms a pn-junction with a partial region of the p-type semiconductor layer. The insulating layer is provided in a region where the pn-junction is not formed between the p-type semiconductor layer and the n-type semiconductor layer. The laminate contains 0.005 wt % to 0.009 wt % of carbon.

In the thermoelectric conversion element according to the present invention, since the laminate contains 0.005 wt % to 0.009 wt % of carbon, the power generation amount is large and the variation in power generation amount is small.

In the thermoelectric conversion element according to the present invention, it is preferred that the p-type semiconductor layer contains an alloy containing at least Ni and the n-type semiconductor layer contains a strontium titanate-based composite oxide containing a rare earth element.

In the thermoelectric conversion element according to the present invention, the rare earth element is preferably at least lanthanum.

In the thermoelectric conversion element according to the present invention, the alloy preferably further contains Mo.

In the thermoelectric conversion element according to the present invention, the p-type semiconductor layer preferably contains a same type of n-type semiconductor material as the n-type semiconductor layer. In this case, the adhesion strength between the p-type semiconductor layer and the n-type semiconductor layer can be improved.

With the above configurations, it is possible to increase a power generation amount of the thermoelectric conversion element and reduce variation in power generation amounts between the thermoelectric conversion elements.

### BRIEF EXPLANATION OF THE DRAWINGS

FIG. 1 is a schematic perspective view of a thermoelectric conversion element according to one embodiment of the present invention.

FIG. 2 is a graph showing output characteristics of a thermoelectric conversion element prepared in Experiment Example 1-1.

FIG. 3 is a graph showing output characteristics of a thermoelectric conversion element prepared in Experiment Example 1-2.

FIG. 4 is a graph showing output characteristics of a thermoelectric conversion element prepared in Experiment Example 1-3.

FIG. 5 is a graph showing output characteristics of a thermoelectric conversion element prepared in Experiment Example 1-4.

FIG. 6 is a graph showing output characteristics of a thermoelectric conversion element prepared in Experiment Example 1-5.

### DETAILED DESCRIPTION OF THE INVENTION

Hereinafter, examples of preferred embodiments of the present invention will be described. However, the following embodiments are merely an exemplification. The present invention is not limited to the following embodiments at all, but only by the appended claims.

(Thermoelectric Conversion Element 1)

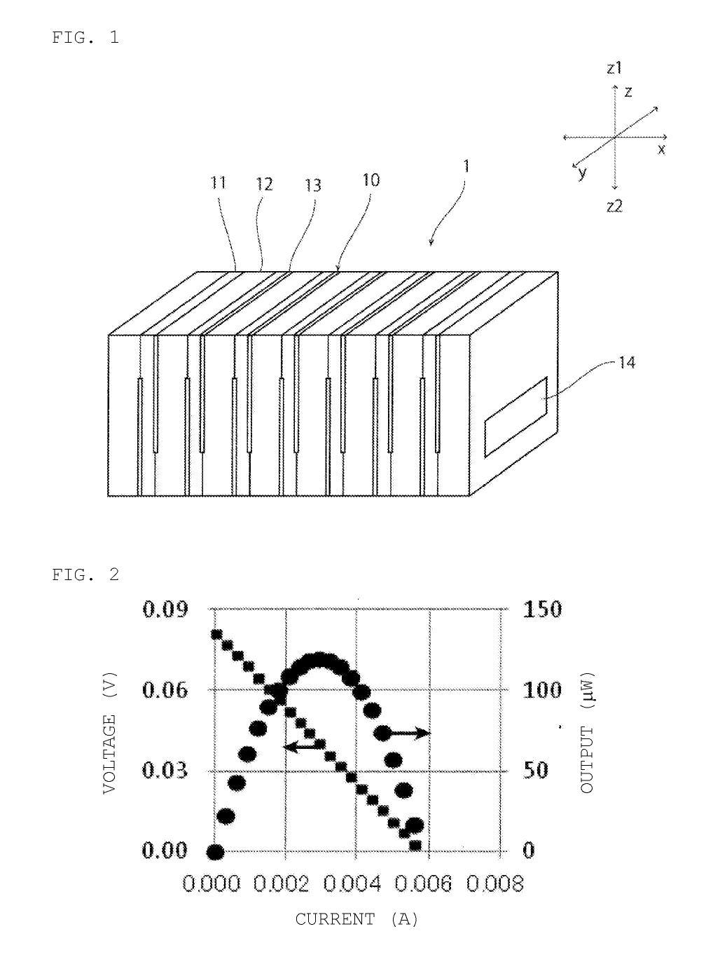

FIG. 1 is a schematic perspective view of a thermoelectric conversion element 1 according to the present embodiment. The thermoelectric conversion element 1 includes a laminate 10. The laminate 10 has, for example, a rectangular parallelepiped shape. In the present invention, the rectangular parallelepiped shape includes a rectangular parallelepiped shape in which ridgeline portions and corner portions are chamfered or rounded.

The laminate 10 has a p-type semiconductor layer 11 and an n-type semiconductor layer 12. Specifically, the laminate 10 includes a plurality of p-type semiconductor layers 11 and a plurality of n-type semiconductor layers 12 alternately laminated. That is, the p-type semiconductor layer 11 and the n-type semiconductor layer 12 adjacent to each other in a lamination direction x are partially in contact with each other. The p-type semiconductor layer 11 and the n-type semiconductor layer 12 adjacent to each other in the lamination direction x form a pn-junction with each other in the contact portion. (Hereinafter, the region where the p-type semiconductor layer 11 and the n-type semiconductor layer 12 form a pn-junction is sometimes referred to as “pn-junction region”.) The pn-junction region is alternately provided along the lamination direction x on a z1 side and a z2 side in a z axis direction perpendicular to the lamination direction x.

The p-type semiconductor layer 11 contains a p-type semiconductor material. In the present embodiment, the p-type semiconductor layer 11 contains as a p-type semiconductor material an alloy containing Ni as a main component. Specific examples of the alloy containing Ni as a main component include NiCr, NiMo, NiW, NiSi, NiCu, NiFe, NiCrFe, NiMoW, and the like. Among them, the p-type semiconductor material is preferably an Ni alloy further containing at least one metal selected from the group consisting of Mo, Cr and W, more preferably a Ni alloy further containing Mo, and still more preferably NiₓMo₁₋ₓ (0.85≤x≤0.95). The p-type semiconductor layer 11 may be composed of only a p-type semiconductor material or may further contain another material in addition to the p-type semiconductor material.

The n-type semiconductor layer 12 contains an n-type semiconductor material. The n-type semiconductor material is preferably a perovskite-type composite oxide represented by the composition formula ABO₃ (each of A and B is one or plural kinds of elements). In the composition formula ABO₃, A preferably contains at least Sr, and B preferably contains at least Ti. A part of Sr in the A site may be site-substituted with a rare earth element such as La, Y, Ce, Sm, Dy, or Er. Specifically, the n-type semiconductor material is preferably a strontium titanate-based composite oxide containing a rare earth element such as La, and more preferably (SrₓLa₍₁₋ₓ₎TiO₃ (0.03≤x≤0.04). The n-type semiconductor layer 12 may be composed of only an n-type semiconductor material or may further contain another material in addition to the n-type semiconductor material.

In the present embodiment, the p-type semiconductor layer 11 and the n-type semiconductor layer 12 contain the same type of n-type semiconductor material. Therefore, the adhesion between the p-type semiconductor layer 11 and the n-type semiconductor layer 12 can be improved. The content of the n-type semiconductor material in the p-type semiconductor layer 11 is preferably 5 mass % or more and 30 mass % or less, and more preferably 15 mass % or more and 25 mass % or less.

An insulating layer 13 is disposed between the p-type semiconductor layer 11 and the n-type semiconductor layer 12 adjacent to each other in the lamination direction x. Specifically, the insulating layer 13 is partially disposed between the p-type semiconductor layer 11 and the n-type semiconductor layer 12 adjacent to each other in the lamination direction x, more specifically, in a region between the p-type semiconductor layer 11 and the n-type semiconductor layer 12 where a pn-junction is not formed.

The insulating layer 13 contains an insulating material. Examples of the insulating material include oxides containing at least one of Si, Al, Zr, Y and the like. Specific examples of the insulating material include silica, alumina, forsterite, yttrium-zirconia composite oxide, and the like. A material of the insulating layer 13 can be appropriately selected depending on the material of the p-type semiconductor layer 11, the material of the n-type semiconductor layer 12, preparation conditions of the laminate 10, and the like.

An external electrode 14 is provided on each of both end surfaces positioned in the lamination direction of the laminate 10. The external electrode 14 can be made of, for example, Ni, NiMo, NiCr or the like.

One p-type semiconductor layer 11 and one n-type semiconductor layer 12 which constitute the laminate 10 and are adjacent to each other are defined as one group. The number of groups of the p-type semiconductor layer 11 and the n-type semiconductor layer 12 constituting the laminate 10 is not particularly limited. The number of groups can be appropriately set depending on characteristics such as a power generation amount to be required. The number of groups is preferably, for example, 10 or more and 100 or less.

In the thermoelectric conversion element 1 according to the present embodiment, when there is a temperature difference between a portion on the z1 side (surface on the z1 side of the laminate 10) and a portion on the z2 side (surface on the z2 side of the laminate 10) in the z axis direction of the thermoelectric conversion element 1, an electromotive force is generated in the thermoelectric conversion element 1 due to the Seebeck effect. Therefore, for example, the thermoelectric conversion element 1 is configured for use to generate a temperature difference between the portion on the z1 side and the portion on the z2 side in the z axis direction of the thermoelectric conversion element 1.

(Method for Producing Thermoelectric Conversion Element 1)

Next, an example of a method for producing the thermoelectric conversion element 1 will be described.

[Preparation of P-Type Semiconductor Green Sheet]

A solvent or the like is added to a material powder such as a metal, or an oxide, a carbonate, a hydroxide, an alkoxide or the like including the metal for forming the p-type semiconductor layer 11 to prepare a slurry. Next, a solvent, a binder or the like is added to the raw material powder to prepare a slurry. By printing the slurry, a p-type semiconductor green sheet is prepared.

[Preparation of N-Type Semiconductor Green Sheet]

A solvent or the like is added to a material powder such as a metal oxide or carbonate, hydroxide, alkoxide or the like for forming the n-type semiconductor layer 12 to prepare a slurry. The slurry is calcined and then pulverized to prepare a raw material powder. Next, a solvent, a binder or the like is added to the raw material powder to prepare a slurry. By printing the slurry, an n-type semiconductor green sheet is prepared.

[Preparation of Insulating Paste Layer]

A resin and an organic solvent are added to a material powder such as a metal oxide or carbonate for forming the insulating layer 13, and the resulting mixture is kneaded to prepare a paste. The paste is printed onto the p-type semiconductor green sheet and the n-type semiconductor green sheet to prepare an insulating paste layer.

[Preparation of Formed Product]

The p-type semiconductor green sheet and the n-type semiconductor green sheet, onto each of which the above-mentioned insulating paste is printed, are appropriately laminated, and then pressed to prepare a formed product.

[Firing of Formed Product]

Next, the formed product is fired to obtain a laminate 10. The firing temperature and firing time of the formed product can be appropriately set according to the materials to be used, characteristics to be required, and the like. The firing temperature of the formed product can be set to, for example, 1200° C. or higher and 1400° C. or lower. The firing time of the formed product can be set to, for example, 1 hour or more and 6 hours or less.

Upon firing the formed product, the p-type semiconductor green sheet contains the same type of n-type semiconductor material as the n-type semiconductor material contained in the n-type semiconductor green sheet, so that the p-type semiconductor green sheet and the n-type semiconductor green sheet are co-fired to form a co-fired body, and the adhesion between the p-type semiconductor layer 11 and the n-type semiconductor layer can be improved.

[Formation of External Electrode 14]

Next, the thermoelectric conversion element 1 can be completed by forming the external electrodes 14 on both end surfaces of the laminate 10. The external electrode 14 can be formed, for example, by applying a metal paste to both end surfaces of the laminate 10 and then firing the paste. The external electrode 14 can also be formed by a sputtering method, a chemical vapor deposition (CVD) method, or the like.

When the thermoelectric conversion element 1 is produced by using the production method as described above, carbon derived from the resin, the solvent, or the binder is contained in the laminate 10 composed of the p-type semiconductor layer 11, the n-type semiconductor layer 12, and the insulating layer 13. As a result of earnest investigations, the present inventors have found that there is a correlation between the carbon content in the laminate 10 and the power generation amount of the thermoelectric conversion element 1 or variation in the power generation amount. Specifically, the present inventors have found that the power generation amount of the thermoelectric conversion element 1 can be increased and the variation in the power generation amount can be reduced by setting the carbon content in the laminate 10 to 0.005 wt % or more and 0.009 wt % or less. In the present embodiment, since the laminate 10 contains carbon in an amount of 0.005 wt % or more and 0.009 wt % or less, the power generation amount of the thermoelectric conversion element 1 can be increased. Further, it is possible to reduce the variation of the power generation amount of the thermoelectric conversion element 1 in production.

When the carbon content in the laminate 10 is less than 0.005 wt %, the variation in the power generation amount of the thermoelectric conversion element 1 becomes large. The reason for this is considered that the n-type semiconductor layer 12 is not suitably formed in many cases, and the characteristics of the n-type semiconductor layer 12 vary.

When the carbon content in the laminate 10 is more than 0.009 wt %, the power generation amount of the thermoelectric conversion element 1 becomes small. The reason for this is considered that the electric resistances of the p-type semiconductor layer 11 and n-type semiconductor layer 12 are increased.

The present invention will be described in more detail below based on specific experiment examples, but the present invention is not limited to the following experiment examples, and variations and modifications may be appropriately made without departing from the gist of the invention.

### Experiment Example 1-1

A thermoelectric conversion element substantially similar to the thermoelectric conversion element 1 according to the above embodiment was prepared in the following manner. The composition of the p-type semiconductor layer and the composition of the n-type semiconductor layer were respectively set to the composition as shown in Table 1.

Specifically, La₂O₃ powder, SrCO₃ powder, TiO₂ powder were prepared as raw materials of the n-type semiconductor material for forming the p-type semiconductor layer 11 and the n-type semiconductor layer 12. These raw materials were weighed so as to have the composition of the n-type semiconductor material shown in Table 1. Pure water was added to the raw material and the resulting mixture was mixed over 16 hours using a ball mill to form a slurry. The slurry was calcined in the air at 1300° C. to obtain an n-type semiconductor material powder.

Next, the n-type semiconductor material powder, metal Ni powder, and metal Mo powder were weighed so as to have the composition of the p-type semiconductor layer shown in Table 1 and pulverized for 5 hours using a ball mill. To the obtained powder were added toluene, EKINEN, a binder and the like to obtain a mixture, and the mixture was further mixed for 16 hours to obtain a slurry. The resulting slurry was formed into a sheet shape with a comma coater to prepare a p-type semiconductor green sheet having a thickness of 50 μm.

Further, the n-type semiconductor material powder was pulverized for 5 hours using a ball mill. To the obtained powder were added toluene, EKINEN, a binder and the like to obtain a mixture, and the mixture was further mixed for 16 hours to obtain a slurry. The resulting slurry was formed into a sheet shape with a comma coater to prepare an n type semiconductor green sheet having a thickness of 200 μm.

Y₂O₃—ZrO₂ powder, varnish and a solvent were mixed as a material of an insulator, and an insulating paste was prepared using a roll machine. The insulating paste was printed onto each of the p-type semiconductor green sheet and the n-type semiconductor green sheet such that the insulating paste had a thickness of 5 μm.

Then, 50 layers of p-type semiconductor green sheets and 50 layers of n-type semiconductor green sheets, onto each of which the insulating layer was printed, were alternately laminated to prepare a laminate. The prepared laminate was pressed by an isostatic pressing method to obtain a formed product. The prepared formed product was cut into a predetermined size with a dicing saw to prepare a base body.

Next, the base body was degreased by being subjected to heating in the air. Thereafter, the degreased base body was heated at a temperature raising rate of 3° C./minute to the temperature shown in Table 1 under an air atmosphere, and then N₂ and H₂ were supplied to bring the air atmosphere into a reducing atmosphere with an oxygen partial pressure of 10^{-12 to -14} MPa, and the degreased base body was fired by heating at 1300° C. for 3 hours to obtain a fired body. The resulting fired body was polished, and then an external electrode was formed, thereby preparing a thermoelectric conversion element. FIG. 2 illustrates a graph showing the output characteristics of the thermoelectric conversion element prepared in Experiment Example 1-1.

### Experiment Example 1-2

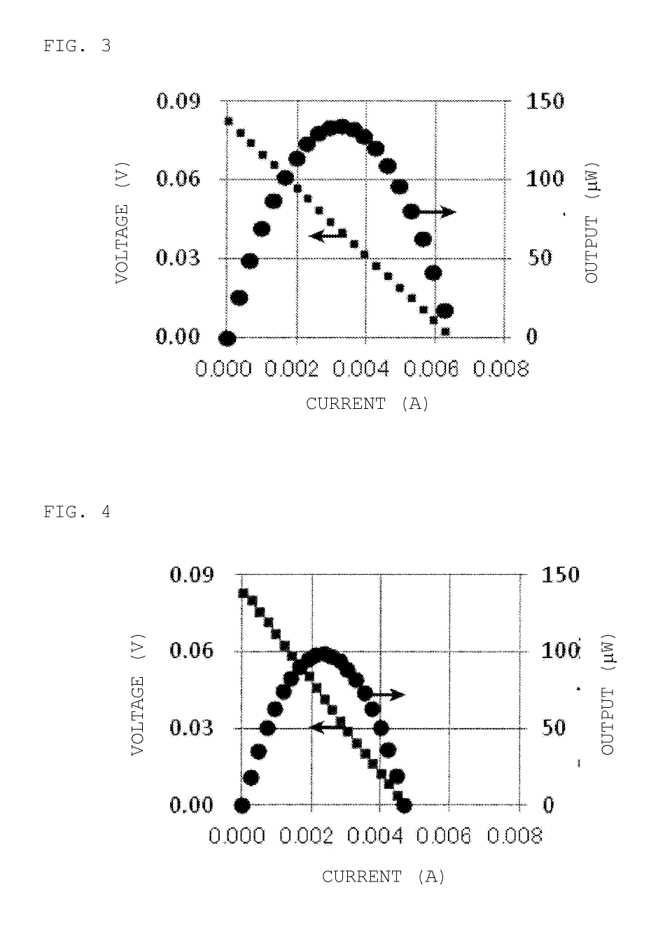

A thermoelectric conversion element was prepared in the same manner as in Experiment Example 1-1 except that the temperature raised under the air atmosphere was changed to the temperature shown in Table 1. FIG. 3 illustrates a graph showing the output characteristics of the thermoelectric conversion element prepared in Experiment Example 1-2.

### Experiment Example 1-3

A thermoelectric conversion element was prepared in the same manner as in Experiment Example 1-1 except that the temperature raised under the air atmosphere was changed to the temperature shown in Table 1. FIG. 4 illustrates a graph showing the output characteristics of the thermoelectric conversion element prepared in Experiment Example 1-3.

### Experiment Example 1-4

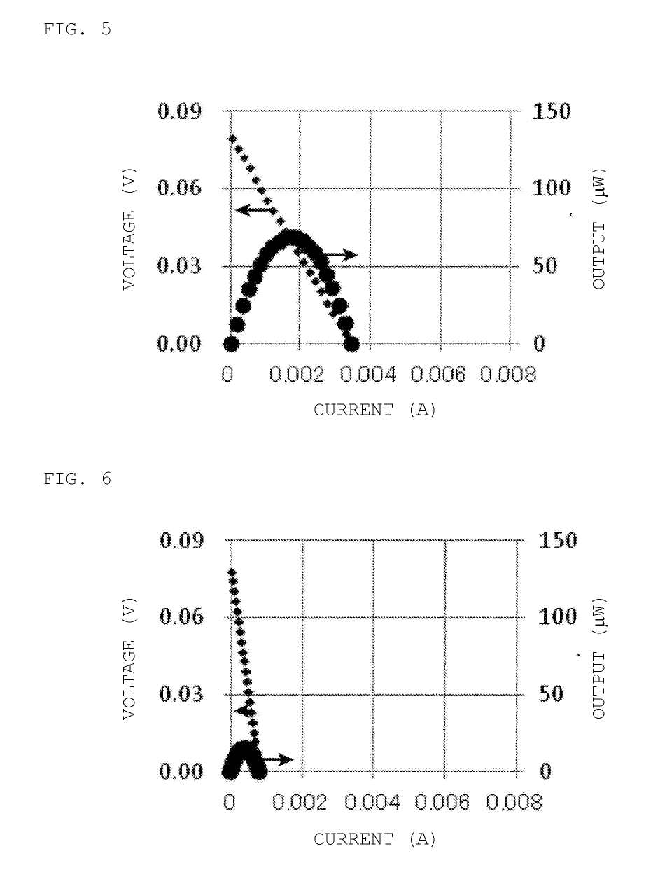

A thermoelectric conversion element was prepared in the same manner as in Experiment Example 1-1 except that the temperature raised under the air atmosphere was changed to the temperature shown in Table 1. FIG. 5 illustrates a graph showing the output characteristics of the thermoelectric conversion elements prepared in Experiment Examples 1-4.

### Experiment Example 1-5

A thermoelectric conversion element was prepared in the same manner as in Experiment Example 1-1 except that the temperature raised under the air atmosphere was changed to the temperature shown in Table 1. FIG. 6 illustrates a graph showing the output characteristics of the thermoelectric conversion elements prepared in Experiment Examples 1-5.

### Experiment Example 2-1

A thermoelectric conversion element was prepared in the same manner as in Experiment Example 1-1 except that the composition of the p-type semiconductor layer and the composition of the n-type semiconductor layer were respectively changed to the composition shown in Table 1.

### Experiment Example 2-2

A thermoelectric conversion element was prepared in the same manner as in Experiment Example 2-1 except that the temperature raised under the air atmosphere was changed to the temperature shown in Table 1.

### Experiment Example 2-3

A thermoelectric conversion element was prepared in the same manner as in Experiment Example 2-1 except that the temperature raised under the air atmosphere was changed to the temperature shown in Table 1.

### Experiment Example 3-1

A thermoelectric conversion element was prepared in the same manner as in Experiment Example 1-1 except that the composition of the p-type semiconductor layer and the composition of the n-type semiconductor layer were respectively changed to the composition shown in Table 1.

### Experiment Example 3-2

A thermoelectric conversion element was prepared in the same manner as in Experiment Example 3-1 except that the temperature raised under the air atmosphere was changed to the temperature shown in Table 1.

### Experiment Example 3-3

A thermoelectric conversion element was prepared in the same manner as in Experiment Example 3-1 except that the temperature raised under the air atmosphere was changed to the temperature shown in Table 1.

### Experiment Example 4-1

A thermoelectric conversion element was prepared in the same manner as in Experiment Example 1-1 except that the composition of the p-type semiconductor layer and the composition of the n-type semiconductor layer were respectively changed to the composition shown in Table 1.

### Experiment Example 4-2

A thermoelectric conversion element was prepared in the same manner as in Experiment Example 4-1 except that the temperature raised under the air atmosphere was changed to the temperature shown in Table 1.

### Experiment Example 4-3

A thermoelectric conversion element was prepared in the same manner as in Experiment Example 4-1 except that the temperature raised under the air atmosphere was changed to the temperature shown in Table 1.

### Experiment Example 5-1

A thermoelectric conversion element was prepared in the same manner as in Experiment Example 1-1 except that the composition of the p-type semiconductor layer and the composition of the n-type semiconductor layer were respectively changed to the composition shown in Table 1.

### Experiment Example 5-2

A thermoelectric conversion element was prepared in the same manner as in Experiment Example 5-1 except that the temperature raised under the air atmosphere was changed to the temperature shown in Table 1.

### Experiment Example 5-3

A thermoelectric conversion element was prepared in the same manner as in Experiment Example 5-1 except that the temperature raised under the air atmosphere was changed to the temperature shown in Table 1.

### Experiment Example 6-1

A thermoelectric conversion element was prepared in the same manner as in Experiment Example 1-1 except that the composition of the p-type semiconductor layer and the composition of the n-type semiconductor layer were respectively changed to the composition shown in Table 1.

### Experiment Example 6-2

A thermoelectric conversion element was prepared in the same manner as in Experiment Example 6-1 except that the temperature raised under the air atmosphere was changed to the temperature shown in Table 1.

### Experiment Example 7-1

A thermoelectric conversion element was prepared in the same manner as in Experiment Example 1-1 except that the composition of the p-type semiconductor layer and the composition of the n-type semiconductor layer were respectively changed to the composition shown in Table 1.

### Experiment Example 7-2

A thermoelectric conversion element was prepared in the same manner as in Experiment Example 7-1 except that the temperature raised under the air atmosphere was changed to the temperature shown in Table 1.

### Experiment Example 7-3

A thermoelectric conversion element was prepared in the same manner as in Experiment Example 7-1 except that the temperature raised under the air atmosphere was changed to the temperature shown in Table 1.

(Measurement Method of Carbon Content in Laminate)

Measurement was performed by an in-oxygen airflow combustion (high-frequency furnace-based)-infrared ray absorption method using EMIA-920V manufactured by HORIBA, Ltd.

(Measurement Method of Power Generation Amount and Coefficient of Variation in Power Generation Amount)

The upper surface of the thermoelectric conversion element prepared in each of Experiment Examples was brought into contact with a heater whose temperature was controlled at 30° C., the lower surface of the thermoelectric conversion element was brought into contact with a cooling plate whose temperature was controlled at 20° C., and a temperature difference between the upper surface and the lower surface of the thermoelectric conversion element was set to 10° C.

A metal probe was brought into contact with a NiMo electrode (external electrode) at a side of the thermoelectric conversion element, a constant current was applied, and the voltage at that time was measured. The voltage was measured by changing a current value, current×voltage=electric power was calculated, and a peak value of electric power was taken as a power generation amount. Further, the power generation amounts of 30 thermoelectric conversion elements were measured, the average value and standard deviation of the power generation amounts were calculated, and the standard deviation was divided by the average value of the power generation amounts to calculate a coefficient of variation in power generation amount. The results are shown in Table 1.

TABLE 1

| | | | | | | Coefficient |
|---|---|---|---|---|---|---|
| | Composition | Composition | Upper Limit | | | of Variation |
| | of P-Type | of n-Type | Temperature | | Power | in Power |
| | Semiconductor | Semiconductor | in Air | Carbon | Generation | Generation |
| | Layer | Layer | Stream | Content | Amount | Amount |
| Experiment | Ni_{0.9}Mo_{0.1} 80 mass % + | (Sr_{0.965}La_{0.035}) | 400° C. | Equal to ot | 120 μW | 18% |
| Example 1-1 | (Sr_{0.965}La_{0.035})TiO₃ 20 mass % | TiO₃ | | less than | | |
| | | | | detection limit | | |
| Experiment | Ni_{0.9}Mo_{0.1} 80 mass % + | (Sr_{0.965}La_{0.035}) | 350° C. | 0.005 mass % | 134 μW | 5% |
| Example 1-2 | (Sr_{0.965}La_{0.035})TiO₃ 20 mass % | TiO₃ | | | | |
| Experiment | Ni_{0.9}Mo_{0.1} 80 mass % + | (Sr_{0.965}La_{0.035}) | 325° C. | 0.008 mass % | 99 μW | 6% |
| Example 1-3 | (Sr_{0.965}La_{0.035})TiO₃ 20 mass % | TiO₃ | | | | |
| Experiment | Ni_{0.9}Mo_{0.1} 80 mass % + | (Sr_{0.965}La_{0.035}) | 300° C. | 0.009 mass % | 69 μW | 5% |
| Example 1-4 | (Sr_{0.965}La_{0.035})TiO₃ 20 mass % | TiO₃ | | | | |
| Experiment | Ni_{0.9}Mo_{0.1} 80 mass % + | (Sr_{0.985}La_{0.035}) | 250° C. | 0.011 mass % | 16 μW | 21% |
| Example 1-5 | (Sr_{0.965}La_{0.035})TiO₃ 20 mass % | TiO₃ | | | | |
| Experiment | Ni_{0.9}Mo_{0.1} 80 mass % + | (Sr_{0.970}La_{0.030}) | 400° C. | Equal to or | 95 μW | 28% |
| Example 2-1 | (Sr_{0.965}La_{0.030})TiO₃ 20 mass % | TiO₃ | | less han | | |
| | | | | detection limit | | |
| Experiment | Ni_{0.9}Mo_{0.1} 80 mass % + | (Sr_{0.970}La_{0.030}) | 350° C. | 0.005 mass % | 125 μW | 7% |
| Example 2-2 | (Sr_{0.965}La_{0.030})TiO₃ 20 mass % | TiO₃ | | | | |
| Experiment | Ni_{0.9}Mo_{0.1} 80 mass % + | (Sr_{0.970}La_{0.030}) | 250° C. | 0.010 mass % | 15 μW | 26% |
| Example 2-3 | (Sr_{0.965}La_{0.030})TiO₃ 20 mass % | TiO₃ | | | | |
| Experiment | Ni_{0.9}Mo_{0.1} 80 mass % + | (Sr_{0.96}La_{0.040}) | 400° C. | Equal to or | 102 μW | 36% |
| Example 3-1 | (Sr_{0.965}La_{0.040})TiO₃ 20 mass % | TiO₃ | | less than | | |
| | | | | detection limit | | |
| Experiment | Ni_{0.9}Mo_{0.1} 80 mass % + | (Sr_{0.96}La_{0.040}) | 350° C. | 0.007 mass % | 116 μW | 5% |
| Example 3-2 | (Sr_{0.965}La_{0.040})TiO₃ 20 mass % | TiO₃ | | | | |
| Experiment | Ni_{0.9}Mo_{0.1} 80 mass % + | (Sr_{0.96}La_{0.040}) | 250° C. | 0.015 mass % | 35 μW | 24% |
| Example 3-3 | (Sr_{0.965}La_{0.040})TiO₃ 20 mass % | TiO₃ | | | | |
| Experiment | Ni_{0.95}Mo_{0.05} 80 mass % + | (Sr_{0.965}La_{0.035}) | 400° C. | Equal to or | 79 μW | 34% |
| Example 4-1 | (Sr_{0.965}La_{0.035})TiO₃ 20 mass % | TiO₃ | | less than | | |
| | | | | detection limit | | |
| Experiment | Ni_{0.95}Mo_{0.05} 80 mass % + | (Sr_{0.965}La_{0.035}) | 350° C. | 0.008 mass % | 93 μW | 5% |
| Example 4-2 | (Sr_{0.965}La_{0.035})TiO₃ 20 mass % | TiO₃ | | | | |
| Experiment | Ni_{0.95}Mo_{0.05} 80 mass % + | (Sr_{0.965}La_{0.035}) | 250° C. | 0.015 mass % | 12 μW | 13% |
| Example 4-3 | (Sr_{0.965}La_{0.035})TiO₃ 20 mass % | TiO₃ | | | | |
| Experiment | Ni_{0.85}Mo_{0.15} 80 mass % + | (Sr_{0.965}La_{0.035}) | 400° C. | Equal to or | 52 μW | 32% |
| Example 5-1 | (Sr_{0.965}La_{0.035})TiO₃ 20 mass % | TiO₃ | | less than | | |
| | | | | detection limit | | |
| Experiment | Ni_{0.85}Mo_{0.15} 80 mass % + | (Sr_{0.965}La_{0.035}) | 350° C. | 0.007 mass % | 113 μW | 9% |
| Example 5-2 | (Sr_{0.965}La_{0.035})TiO₃ 20 mass % | TiO₃ | | | | |
| Experiment | Ni_{0.85}Mo_{0.15} 80 mass % + | (Sr_{0.965}La_{0.035}) | 250° C. | 0.018 mass % | 16 μW | 34% |
| Example 5-3 | (Sr_{0.965}La_{0.035})TiO₃ 20 mass % | TiO₃ | | | | |
| Experiment | Ni_{0.9}Mo_{0.1} 85 mass % + | (Sr_{0.965}La_{0.035}) | 400° C. | Equal to or | 124 μW | 19% |
| Example 6-1 | (Sr_{0.965}La_{0.035})TiO₃ 15 mass % | TiO₃ | | less than | | |
| | | | | detection limit | | |
| Experiment | Ni_{0.9}Mo_{0.1} 85 mass % + | (Sr_{0.965}La_{0.035}) | 350° C. | 0.006 mass % | 139 μW | 5% |
| Example 6-2 | (Sr_{0.965}La_{0.035})TiO₃ 15 mass % | TiO₃ | | | | |
| Experiment | Ni_{0.9}Mo_{0.1} 75 mass % + | (Sr_{0.965}La_{0.035}) | 400° C. | Equal to or | 72 μW | 28% |
| Example 7-1 | (Sr_{0.965}La_{0.035})TiO₃ 25 mass % | TiO₃ | | less than | | |
| | | | | detection limit | | 9% |
| Experiment | Ni_{0.9}Mo_{0.1} 75 mass % + | (Sr_{0.965}La_{0.035}) | 350° C. | 0.009 mass % | 93 μW | |
| Example 7-2 | (Sr_{0.965}La_{0.035})TiO₃ 25 mass % | TiO₃ | | | | |
| Experiment | Ni_{0.9}Mo_{0.1} 75 mass % + | (Sr_{0.965}La_{0.035}) | 250° C. | 0.020 mass % | 9 μW | 33% |
| Example 7-3 | (Sr_{0.965}La_{0.035})TiO₃ 25 mass % | TiO₃ | | | | |

In Table 1, Experiment Examples 1-1, 1-5, 2-1, 2-3, 3-1, 3-3, 4-1, 4-3, 5-1, 5-3, 6-1, 7-1, and 7-3 are comparative examples outside the scope of the present invention. Among them, Experiment Example 1-5 is a conventional example.

### DESCRIPTION OF REFERENCE SYMBOLS

1: Thermoelectric conversion element
10: Laminate
11: P-type semiconductor layer
12: N-type semiconductor layer
13: Insulating Layer
14: External electrode

1. A thermoelectric conversion element comprising a laminate having:
a p-type semiconductor layer;
an n-type semiconductor layer positioned adjacent the p-type semiconductor layer so as to form a pn-junction region with the p-type semiconductor layer; and
an insulating layer in a region where the pn-junction region is not formed between the p-type semiconductor layer and the n-type semiconductor layer,
wherein the laminate contains 0.005 wt % to 0.009 wt % of carbon.

2. The thermoelectric conversion element according to claim 1, wherein the pn-junction region is alternately provided along opposing sides of the laminate along a lamination direction thereof.

3. The thermoelectric conversion element according to claim 1, wherein
the p-type semiconductor layer contains an alloy containing at least Ni, and
the n-type semiconductor layer contains a strontium titanate-based composite oxide containing a rare earth element.

4. The thermoelectric conversion element according to claim 3, wherein the rare earth element is at least lanthanum.

5. The thermoelectric conversion element according to claim 4, wherein the alloy further contains Mo.

6. The thermoelectric conversion element according to claim 3, wherein the alloy further contains Mo.

7. The thermoelectric conversion element according to claim 3, wherein the alloy is selected from NiCr, NiMo, NiW, NiSi, NiCu, NiFe, NiCrFe, and NiMoW.

8. The thermoelectric conversion element according to claim 3, wherein the alloy is NiₓMo₁₋ₓ, and 0.85≤x≤0.95.

9. The thermoelectric conversion element according to claim 1, wherein the n-type semiconductor material is a perovskite-type composite oxide represented by ABO₃.

10. The thermoelectric conversion element according to claim 9, wherein, in the perovskite-type composite oxide represented by ABO₃, the A site contains at least Sr, and the B site contains at least Ti.

11. The thermoelectric conversion element according to claim 10, wherein a part of the Sr in the A site is substituted with a rare earth element.

12. The thermoelectric conversion element according to claim 9, wherein the n-type semiconductor material is (SrₓLa_{(1-X)})TiO₃, and 0.03≤x≤0.04.

13. The thermoelectric conversion element according to claim 1, wherein the p-type semiconductor layer contains a same type of n-type semiconductor material as the n-type semiconductor layer.

14. The thermoelectric conversion element according to claim 13, wherein a content of the n-type semiconductor material in the p-type semiconductor layer is 5 mass % to 30 mass %.

15. The thermoelectric conversion element according to claim 13, wherein a content of the n-type semiconductor material in the p-type semiconductor layer is 15 mass % to 25 mass %.

16. The thermoelectric conversion element according to claim 1, wherein a material of the insulating layer is selected from oxides containing at least one of Si, Al, Zr, and Y.

17. The thermoelectric conversion element according to claim 1, wherein a material of the insulating layer is selected from silica, alumina, forsterite, and yttrium-zirconia composite oxide.

18. The thermoelectric conversion element according to claim 1, further comprising an external electrode on each respective end surface in a lamination direction of the laminate.
